(19) United States
(12) Patent Application Publication
(10) Pub. No.: US 2014/0001024 A1
(43) Pub. Date: Jan. 2, 2014

(54) TOUCH PANEL AND TOUCH DISPLAY DEVICE

(71) Applicant: INNOLUX CORPORATION, Chu-Nan (TW)

(72) Inventors: Chen-Kai LIAO, Chu-Nan (TW); Chun-Hung HUANG, Chu-Nan (TW)

(21) Appl. No.: 13/921,621

(22) Filed: Jun. 19, 2013

(30) Foreign Application Priority Data
Jun. 29, 2012 (TW) 101123392

(51) Int. Cl. H03K 17/96

(52) U.S. Cl. CPC H03K 17/9622
USPC 200/600

(57) ABSTRACT

The invention provides a touch display device, including: a plurality of driving electrodes disposed in parallel in a first direction; and a plurality of sensing electrodes disposed in parallel in a second direction, wherein each of the sensing electrodes are split into a plurality of electrode strips, and the electrode strips converge at a minimum, of two ends of the sensing electrode.

### CROSS REFERENCE TO RELATED APPLICATIONS

This Application claims priority of Taiwan Patent Application No. 101123392, filed on Jun. 29, 2012, the entirety of which is incorporated by reference herein.

### BACKGROUND OF THE INVENTION

1. Field of the Invention

The present invention relates to a touch panel and a touch display device, and in particular, relates to a touch panel and a touch display device capable of increasing touch sensitivity.

2. Description of the Related Art

Currently, well-known touch screen techniques, such as resistive touch screens, projected capacitive touch screens, or optical touch screens, are widely applied to various kinds of display devices. The resistive touch screens and projected capacitive touch screens are suited to be applied to portable devices. The projected capacitive touch screens are especially suited to be applied to the portable devices which need to precisely identify different touch input operations by more than one finger, for example, smart phones or tablet computers.

In the projected capacitive touch screen, a touch panel having X-directional and Y-directional electrodes is disposed on a display panel. When a finger or a touch object touches the screen, coupling capacitance between the X-directional and Y-directional electrodes at the touch point varies because of capacitance between the finger or the touch object and the electrodes. A control chip functions to detect the difference of the coupling capacitance and calculate the touch point. In a layout of electrodes of a conventional projected capacitive touch panel as FIG. 1, sensing electrodes Rx are arranged along a Y direction and driving electrodes Tx are arranged along an X direction, wherein the driving electrodes Tx use bridges Br to stride across the sensing electrodes Rx. However, in consideration of lowering the noise from the display panel to increase touch sensitivity, the conventional layout method has lots of room for improvement.

### BRIEF SUMMARY OF THE INVENTION

A detailed description is given in the following embodiments with reference to the accompanying drawings.

To solve the above mentioned problem, the invention provides a touch display device, including: a plurality of driving electrodes disposed in parallel in a first direction; and a plurality of sensing electrodes disposed in parallel in a second direction, wherein each of the sensing electrodes are split into a plurality of electrode strips, and the electrode strips converge at a minimum, of two ends of the sensing electrode.

According to one embodiment of the invention, the sum of the widths of the plurality of electrode strips of the sensing electrode is less than the width of the driving electrode. In addition, according to one embodiment of the invention, the plurality of electrode strips further converge between two adjacent driving electrodes.

According to one embodiment of the invention, the touch display device further comprises a substrate, wherein the plurality of driving electrodes and plurality of sensing electrodes are disposed on two opposite surfaces of the substrate, respectively, or on the same surface of the substrate.

When the plurality of driving electrodes and plurality of sensing electrodes are disposed on the same surface of the substrate, each of the driving electrodes is divided by the electrode strips into several areas, and the adjacent areas of the driving electrode are connected together by at least one bridge which strides across the electrode strip between the adjacent areas.

The invention also provides a touch panel, including: a substrate; a plurality of driving electrodes disposed in parallel in a first direction on a first surface of the substrate; and a plurality of sensing electrodes disposed in parallel in a second direction on a second surface of the substrate, wherein each of the sensing electrodes are split into a plurality of electrode strips, and the electrode strips converge at a minimum, of two ends of the sensing electrode.

The invention also provides a touch panel, including: a substrate; a plurality of driving electrodes disposed in parallel in a first direction on a first surface of the substrate; and a plurality of sensing electrodes disposed in parallel in a second direction on the first surface of the substrate, wherein each of the sensing electrodes are split into a plurality of electrode strips, and the electrode strips converge at a minimum, of two ends of the sensing electrode.

According to one embodiment of the invention, in the above mentioned two kinds of touch panels, the sum of the widths of the plurality of electrode strips of the sensing electrode is less than the width of the driving electrode. Further, according to one embodiment of the invention, the plurality of electrode strips further converge between two adjacent driving electrodes. When the plurality of driving electrodes and plurality of sensing electrodes are disposed on the same surface of the substrate, according to one embodiment of the invention, each of the driving electrodes is divided by the electrode strips into several areas, and the adjacent areas of the driving electrode are connected together by at least one bridge which strides across the electrode strip between the adjacent areas.

### BRIEF DESCRIPTION OF THE DRAWINGS

The present invention can be more fully understood by reading the subsequent detailed description and examples with references made to the accompanying drawings, wherein:

FIG. 1 is a conventional layout of diamond-patterned driving electrodes and diamond-patterned sensing electrodes.

FIG. 2 is a layout of driving electrodes and sensing electrodes in accordance with Embodiment 1 of the invention.

FIG. 3 is an A-A′ section view of the layout shown in FIG. 2.

FIG. 4A shows a unit of a conventional diamond-patterned electrode.

FIG. 4B shows a unit of a branch-patterned electrode in accordance with Embodiment 1.

FIG. 5A is a schematic diagram showing lateral capacitance between conventional diamond-patterned electrodes.

FIG. 5B is a schematic diagram showing lateral capacitance between branch-patterned electrodes in accordance with Embodiment 1.

FIG. 6A is a schematic diagram showing vertical capacitance at the location of a bridge of conventional diamond-patterned electrodes.

FIG. 6B is a schematic diagram showing vertical capacitance at the location of a bridge of branch-patterned electrodes in accordance with Embodiment 1.

FIG. 7 is a layout of driving electrodes and sensing electrodes in accordance with Embodiment 2 of the invention.

FIG. 8 is a layout of driving electrodes and sensing electrodes in accordance with Embodiment 3 of the invention.

FIG. 9 is a layout of driving electrodes and sensing electrodes in accordance with Embodiment 4 of the invention.

FIG. 10 is a layout of driving electrodes and sensing electrodes in accordance with Embodiment 5 of the invention.

FIG. 11 is a B-B′ section view of the layout shown in FIG. 10.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

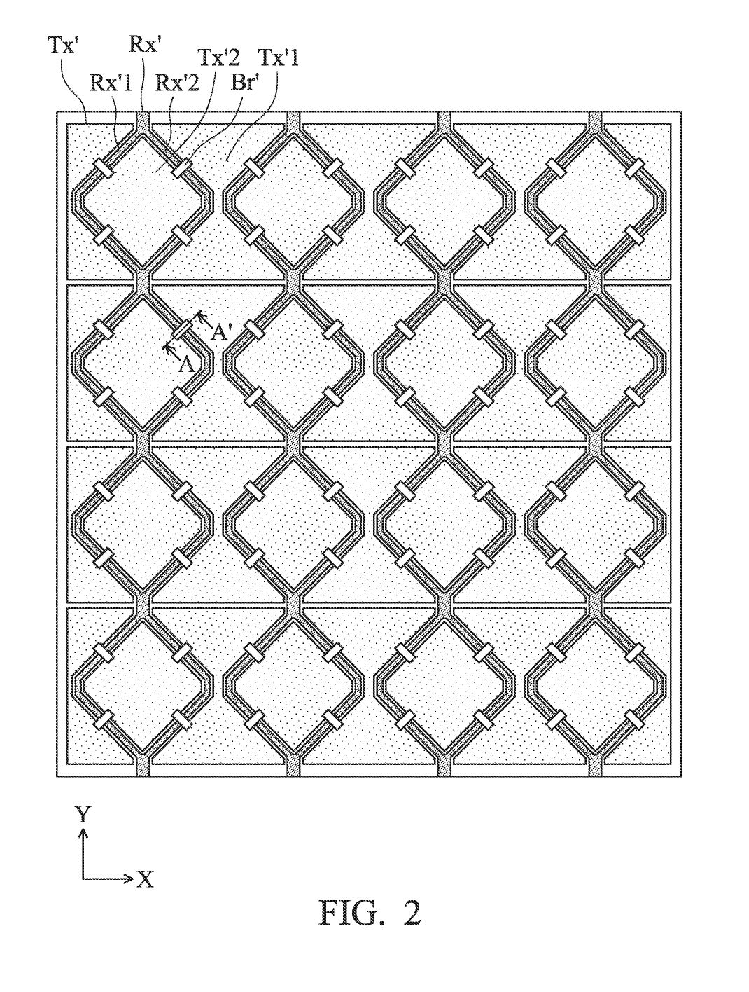

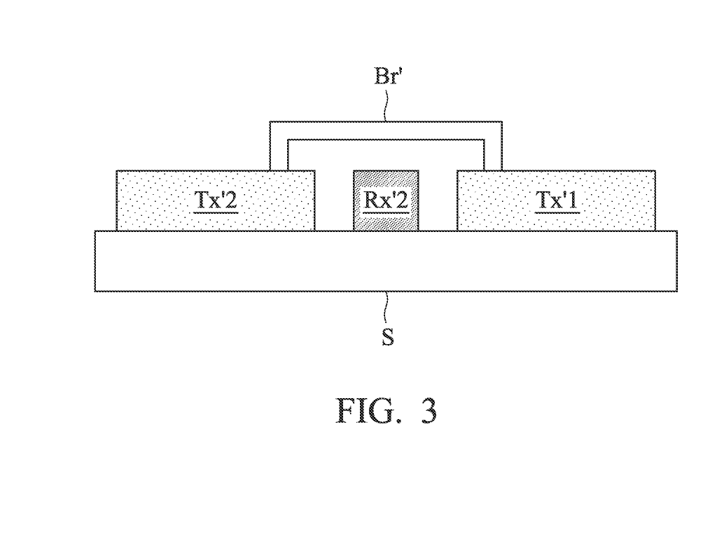

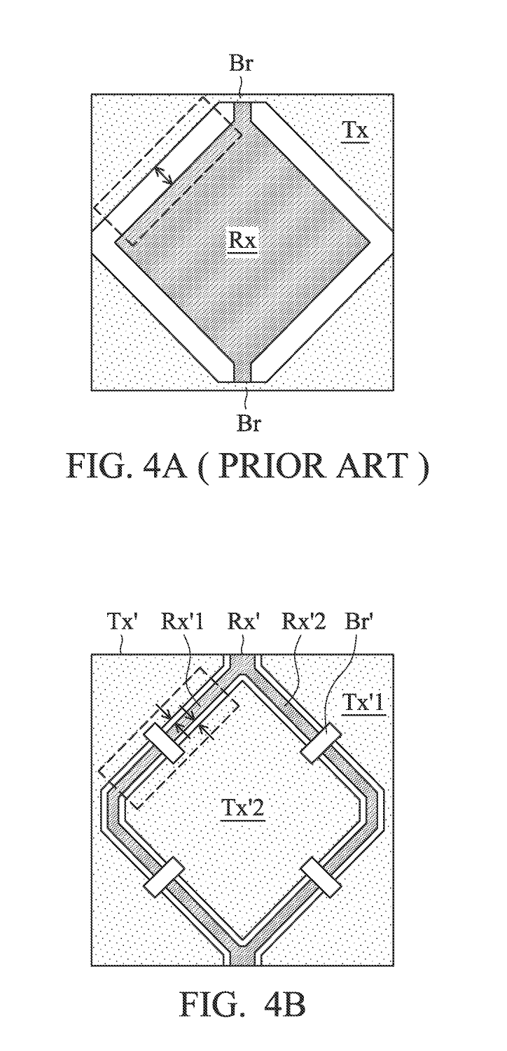

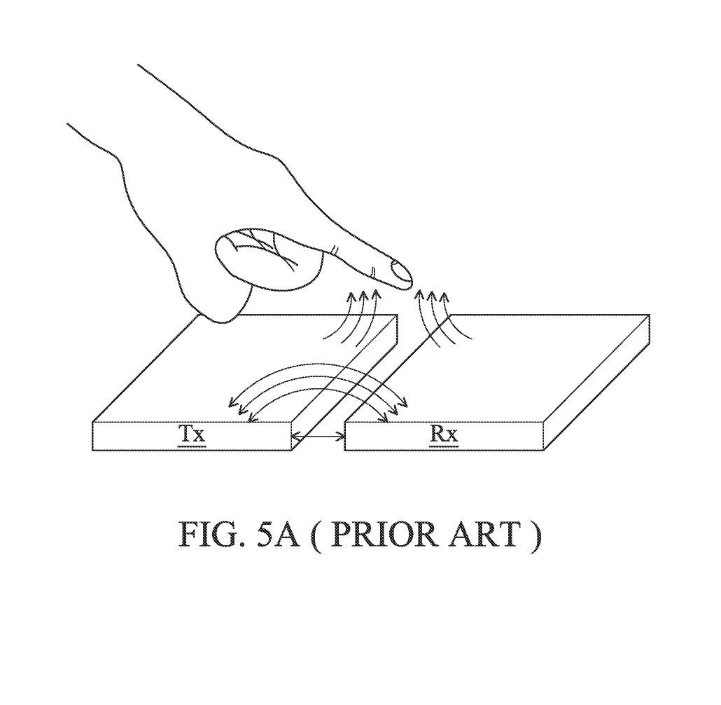

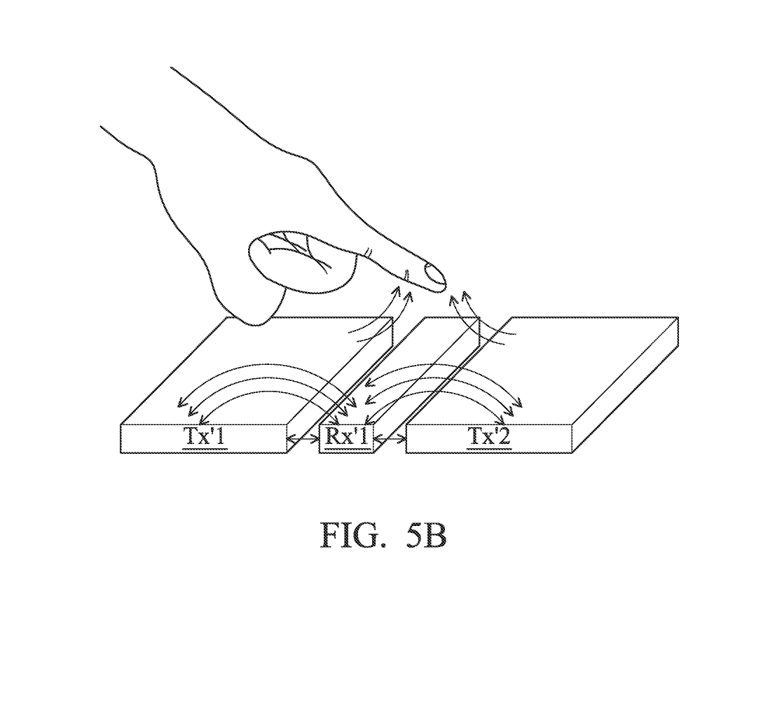

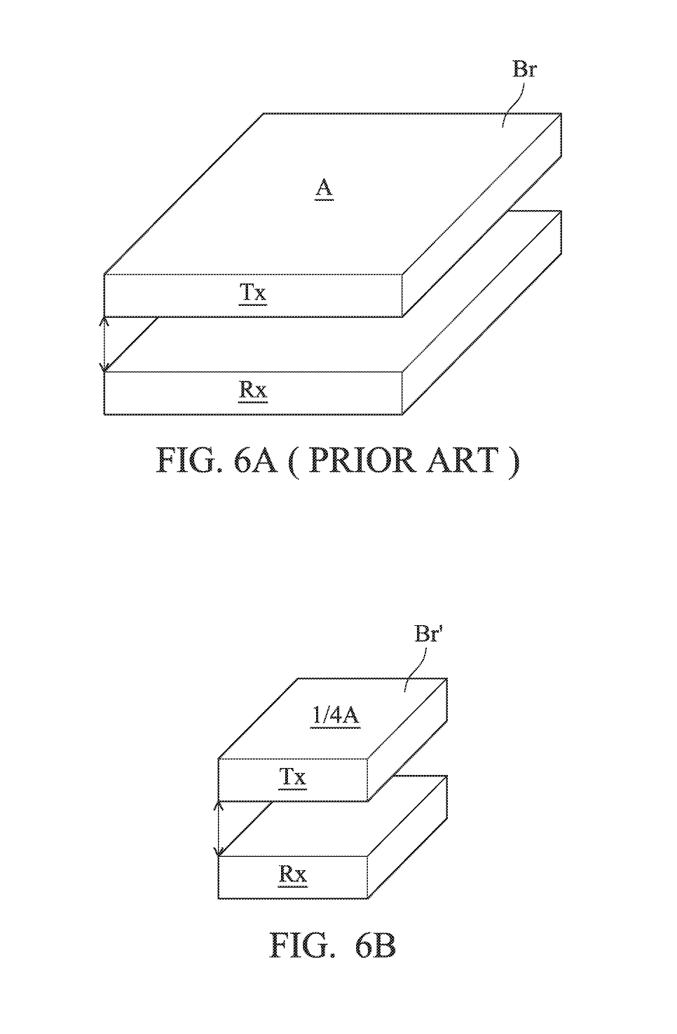

Refer to FIGS. 2-6. FIG. 2 is a layout of driving electrodes and sensing electrodes in accordance with Embodiment 1 of the invention. FIG. 3 is an A-A′ section view of the layout shown in FIG. 2. FIG. 4A shows a unit of a conventional diamond-patterned electrode. FIG. 4B shows a unit of a branch-patterned electrode in accordance with Embodiment 1. FIG. 5A is a schematic diagram showing lateral capacitance between conventional diamond-patterned electrodes. FIG. 5B is a schematic diagram showing lateral capacitance between branch-patterned electrodes in accordance with Embodiment 1. FIG. 6A is a schematic diagram showing vertical capacitance at the location of a bridge of conventional diamond-patterned electrodes. FIG. 6B is a schematic diagram showing vertical capacitance at the location of a bridge of branch-patterned electrodes in accordance with Embodiment 1.

As shown in FIG. 2, the driving electrodes Tx′ extend along an X direction and the sensing electrodes extend along a Y direction. Each sensing electrode Rx′ is split into two electrode strips Rx′1 and Rx′2 at one end and then the electrode strips Rx′1 and Rx′2 converge between two adjacent driving electrodes Tx′. In this way, the electrode strips Rx′1 and Rx′2 diverge and converge repeatedly until reaching the other end of the sensing electrode Rx′. On the other hand, each driving electrode Tx′ is divided by the electrode strips Rx′1 and Rx′2 of the sensing electrode Rx′ into two parts: an area Tx′1 surrounding the sensing electrode Rx′ and an area Tx′2 surrounded by the sensing electrode Rx′.

The disposition of the driving electrode Tx′ and the sensing electrode Rx′ can be easily understood from the A-A′ section view of the layout shown in FIG. 3. In the embodiment, the touch panel is a single ITO (SITO) structure. Namely, the driving electrode Tx′ and the sensing electrode Rx′ are disposed on the same surface of a substrate S. Because the driving electrode Tx′ and the sensing electrode Rx′ cannot contact each other, the area Tx′1 and the area Tx′2 of the one driving electrode Tx′ have to be connected through a bridge Br′.

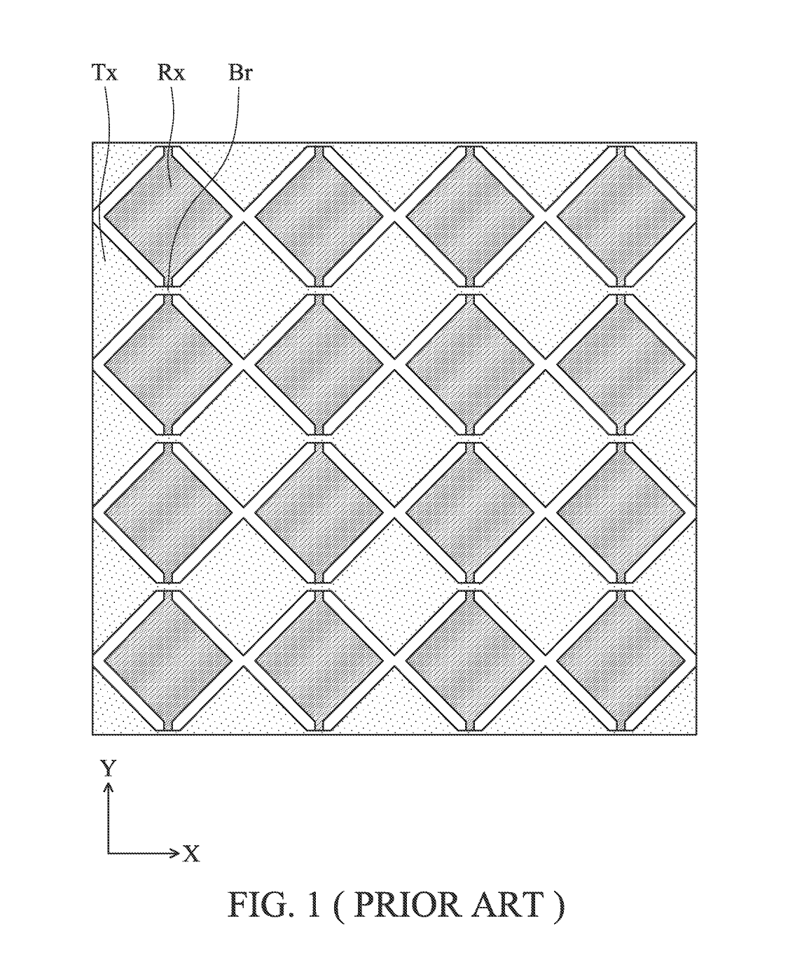

Because the area of the sensing electrode Rx′ formed by the electrode strips (shown in FIG. 2) is substantially smaller than the area of the sensing electrode Rx formed by series connection of diamond patterns (shown in FIG. 1), the sensing electrode Rx′ receives lower noise from the display panel below the touch panel. The noise resistibility of the touch panel is raised effectively. According to the structure of the embodiment, a small section area of the sensing electrode Rx′ may increase the resistance thereof. However, In the branch structure of the sensing electrode Rx′, it can be considered that the resistance of the electrode strip Rx′1 and the resistance of the electrode strip Rx′2 are connected in parallel to decrease the total resistance. Under limited driving power, the sensing electrode Rx′ having low resistance can be applied to large-scale display devices that need more sensing channels.

Furthermore, FIGS. 4A and 4B are used to compare a unit of a conventional diamond-patterned electrode and a unit of a branch-patterned electrode of the embodiment. In the dotted line block, the conventional diamond-patterned sensing electrode Rx shown in FIG. 4A only has one side to face the driving electrode Tx. On the contrary, the electrode strip Rx′1 of the branch-patterned sensing electrode Rx′ has two sides to face the driving electrode Tx (the electrode strip Rx′1 faces the areas Tx′1 and Tx′2). Therefore, in the branch-patterned electrode layout, the lateral area between the driving electrode Tx′ and the sensing electrode Rx′ for generating capacitance is twice the size of that of the conventional layout. This can bring the results shown in FIGS. 5A and 5B. In a touch operation, the finger as shown in FIG. 5A takes away a part of electric lines of force between the driving electrode Tx and the sensing electrode Rx. However, the finger as shown in FIG. 5B takes away a part of electric lines of force between the area Tx′1 of the driving electrode Tx and the electrode strip Rx′1 of the sensing electrode Rx′ and a part of the electric lines of force between the area Tx′2 of driving electrode Tx and the electrode strip Rx′1 of the sensing electrode Rx′. Therefore, the difference of capacitance before and after the touch is increased. In comparison with the conventional diamond-patterned electrode layout, the branch-patterned electrode layout can detect a smaller touch area; especially, under a high noise environment, the difference of capacitance is subtracted by the noise influence, so the larger difference of capacitance benefits the control chip to calculate the location of the touch points more accurately, which raises touch sensitivity and accuracy.

Back to FIGS. 4A and 4B. A unit of the diamond-patterned electrode shown in FIG. 4A has a half bridge Br at the upper boundary and another half bridge Br at the lower boundary. Namely, Each unit has a complete bridge Br. However, a unit of the branch-patterned electrode shown in FIG. 4B has 4 complete bridges Br′. Because the number of the bridges in the branch-patterned electrode is more than that in the diamond-patterned electrode, in the case where the area of the one bridge Br is equal to the area of the one bridge Br′, the branch-patterned electrode has a larger vertical capacitance due to the bridges and the electrodes under the bridges than the diamond-patterned electrode. This result also increases the difference of capacitance before and after a touch so that touch sensitivity is raised. If the branch-patterned electrode is required to have the same vertical capacitance as the diamond-patterned electrode, as shown in FIGS. 6A and 6B, assuming that the area of a bridge Br in the diamond-patterned electrode is A, the area of a bridge Br′ in the branch-patterned electrode can be reduced to ¼ A. Therefore, the difference of capacitance in a unit can be easily controlled by adjusting the area of the bridge Br′. Furthermore, decreasing the area of the bridge makes the bridge hard to be noticed by a viewer. In this regard, the panel product is more elegant in its appearance.

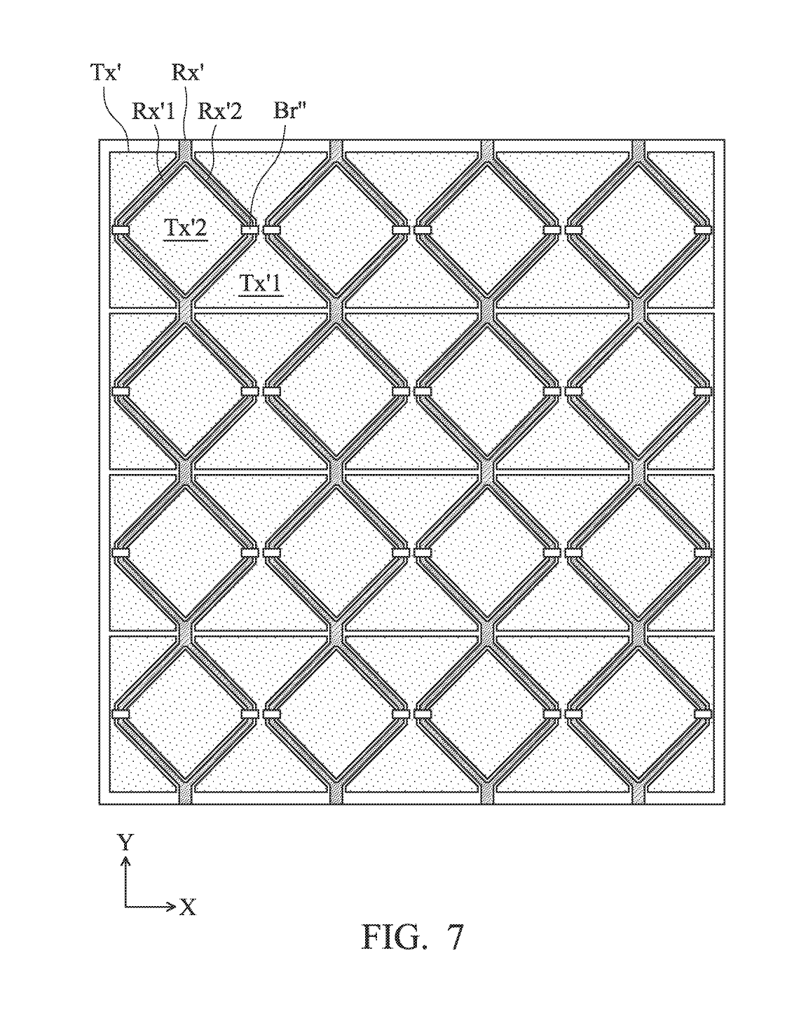

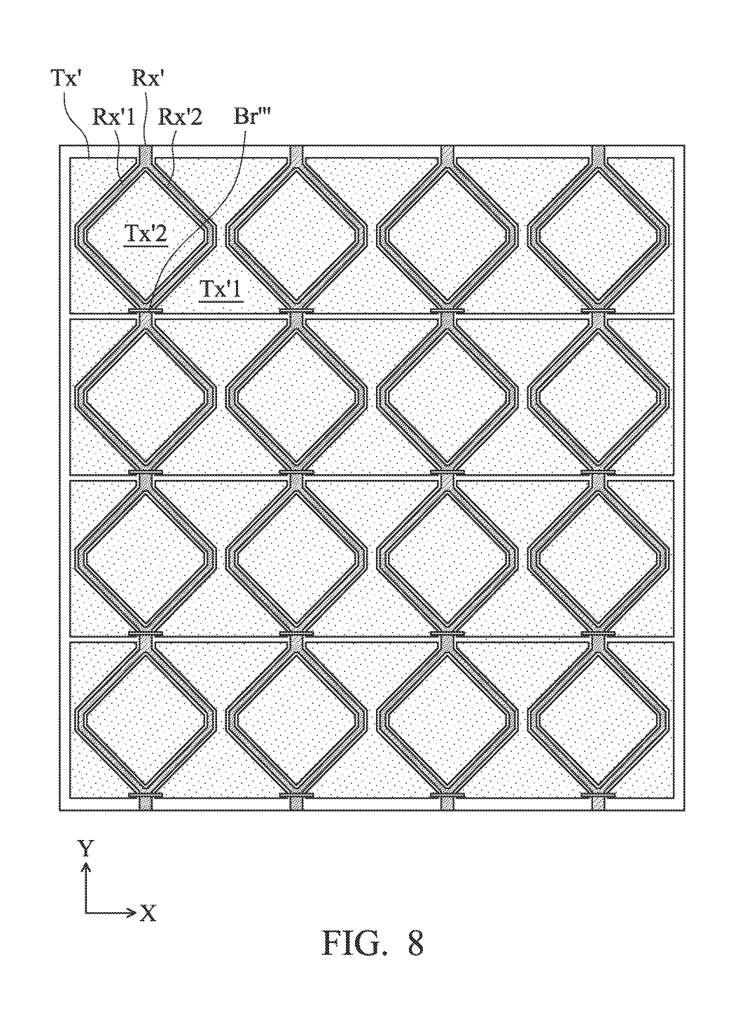

FIG. 7 is a layout of driving electrodes and sensing electrodes in accordance with Embodiment 2 of the invention. FIG. 8 is a layout of driving electrodes and sensing electrodes in accordance with Embodiment 3 of the invention. As shown in FIG. 7, the branch-patterned electrode layout of Embodiment 2 is the same as that of Embodiment 1. Namely. The sensing electrode Rx′ is split into two electrode strips Rx′1 and Rx′2 and the driving electrode Tx′ is divided into two areas Tx′1 and Tx′2. However, the number of the bridges Br′ in a unit of Embodiment 2 is changed from 4 to 2. Furthermore, in order to further decrease the number of the bridges, the bridge Br′″ is moved to the location where the electrode strips Rx′1 and Rx′2 of the sensing electrode Rx′ converge, and are only connected between two adjacent areas Tx′1. In this case, the number of the bridge Br′ in a unit is decreased to 1. In the invention, as long as the bridge connects to adjacent areas of the driving electrode to make the signal be able to transmit from an end of the panel to the opposite end, the number of the bridges is not limited. Note that the advantage of more bridges has been described before. That is, the difference of capacitance can be increased to raise the touch sensitivity and the area of each bridge can be decreased to improve the appearance of the panel product.

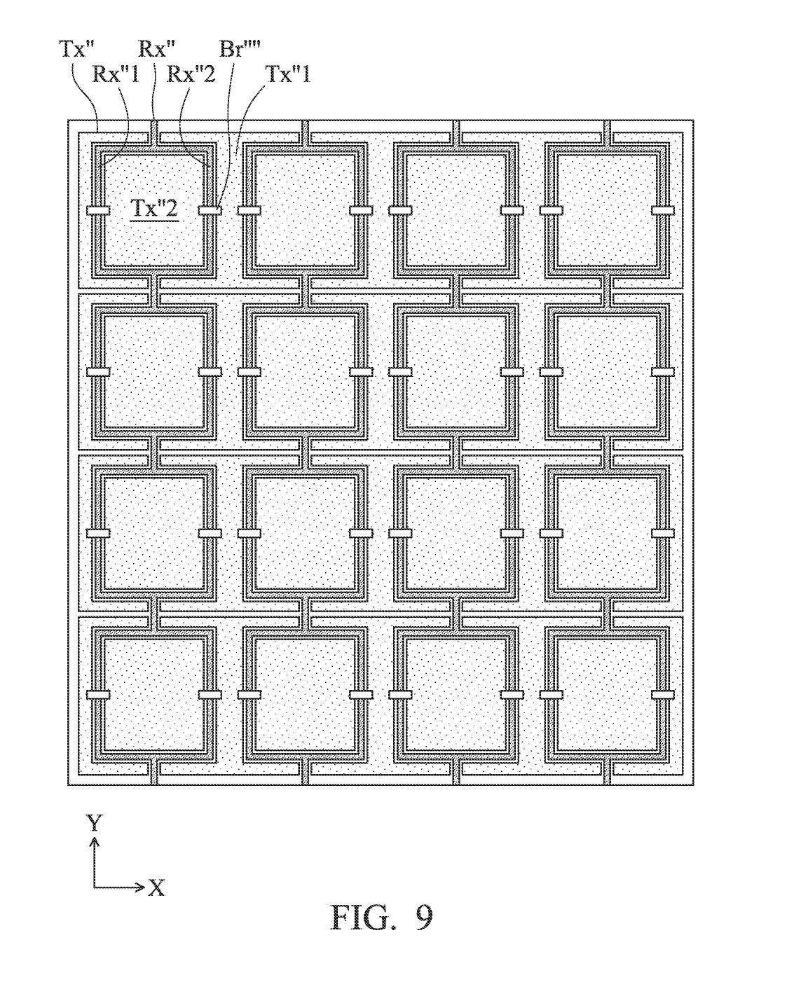

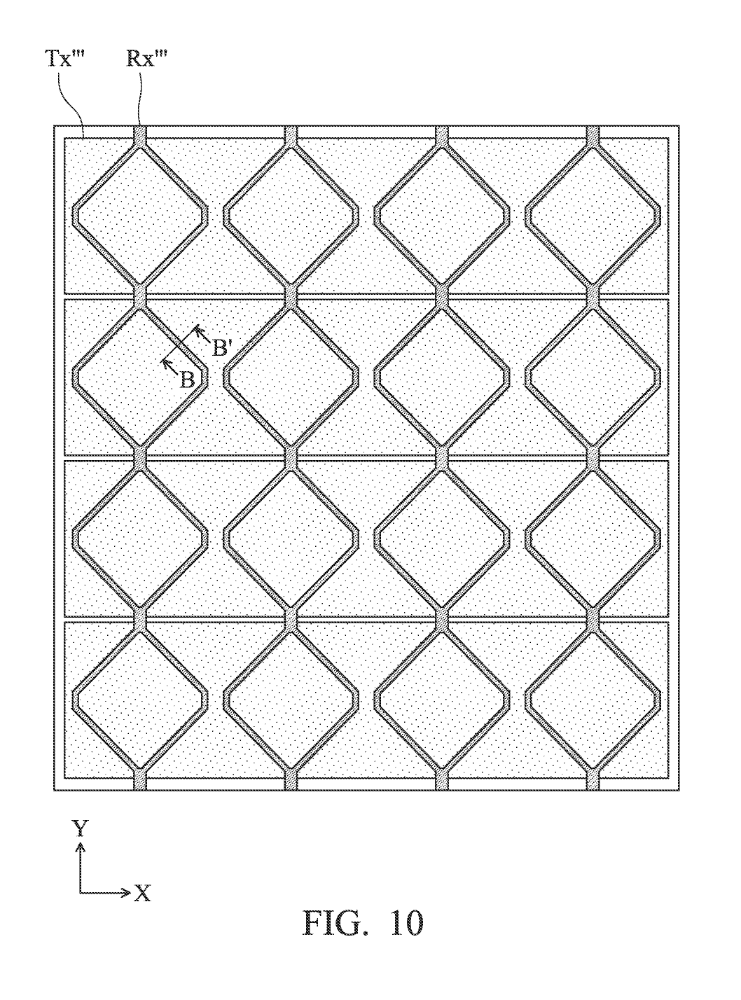

FIG. 9 is a layout of driving electrodes and sensing electrodes in accordance with Embodiment 4 of the invention. In FIG. 9, the sensing electrode Rx″ is also a branch structure, but in each unit the shape surrounded by the electrode strips Rx″1 and Rx″2 of the sensing electrode Rx″ is a square rather than a diamond. In this case, each unit has two bridges Br′″. In Embodiment 1, a diamond shape surrounded by the electrode strips Rx′1 and Rx′2 of the sensing electrode Rx′ is for providing a comparison example with the conventional diamond-patterned sensing electrode Rx. However, the shape surrounded by the electrode strips is not limited. Therefore, a square shape surrounded by the electrode strips Rx″1 and Rx″2 of the sensing electrode Rx″, as shown in Embodiment 4, is also appropriate in the invention.

According to Embodiments 1-4, in the branch patterned electrode layout of the invention, the number of the bridges is not limited and the shape surrounded by the electrode strips is not limited either. In this regard, various kinds of modifications for the branch patterned electrode layout can be made. For example, the number of electrode stripes split from a sensing electrode can be more than 2, or electrode strips split from a sensing electrode can converge only at the ends of the sensing electrode rather than between every two adjacent driving electrodes.

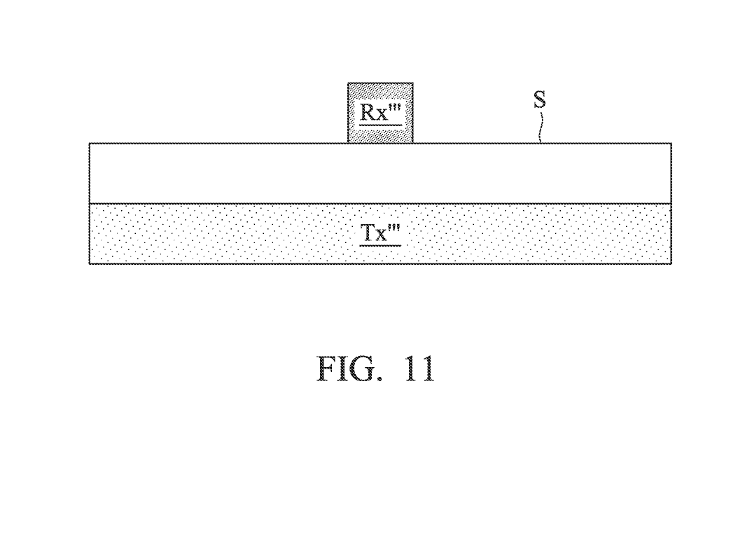

In Embodiments 1-4, it is assumed that the touch panel is a SITO structure. However, the branch patterned electrode layout of the invention is also applicable to a double ITO structured (DITO) touch panel. FIG. 10 is a layout of driving electrodes and sensing electrodes in accordance with Embodiment 5 of the invention. FIG. 11 is a B-B′ section view of the layout shown in FIG. 10.

As shown in FIG. 10, the sensing electrode Rx′ is the same as the sensing electrode Rx′ of Embodiment 1 in appearance. Namely, the sensing electrode Rx′″ is also a branch structure. However, the driving electrodes Tx′″ and the sensing electrodes Rx′″ are not located on the same surface, so that each driving electrode Tx′″ is not divided by the sensing electrodes Rx′″ into several areas. Each driving electrode Tx′″ is a complete long strip. Accordingly, the bridge is unnecessary in this structure.

The disposition of the driving electrode Tx′″ and the sensing electrode Rx′″ can be easily understood from the B-B′ section view of the layout shown in FIG. 11. In FIG. 11, it can be seen that the sensing electrode is located at the upper surface of the substrate S and the driving electrode Tx′″ is located at the lower surface of the substrate S. Because the noise resistibility of a driving electrode is stronger than a sensing electrode, in the DITO structure, the driving electrode Tx″′ can be disposed below the substrate S with a large area (each driving electrode is a complete strip structure) to shield the sensing electrode Rx′″ from the noise due to signals of the display panel. In this way, the signal-to-noise ratio (SNR) can be raised to improve the detection accuracy of the touch panel.

From Embodiment 5, it is understood that the branch patterned electrode can be applied to a DITO structured touch panel. Therefore, all modifications of the structure of the sensing electrode for the SITO structured touch panel are also applicable to the DITO structured touch panel. The structure of the sensing electrode for the DITO structured touch panel is not limited to the structure of Embodiment 5.

According to the above embodiments, the invention provides a touch panel or a touch display device, wherein the touch panel has a branch-patterned electrode layout. With this layout, touch sensitivity and noise resistibility can be raised, and the number of channels can be increased for large-scale display devices. In some embodiments of the invention, the area of bridges can be reduced to improve the appearance of the panel product.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A touch display device, comprising:
a plurality of driving electrodes disposed in parallel in a first direction; and
a plurality of sensing electrodes disposed in parallel in a second direction,
wherein each of the sensing electrodes are split into a plurality of electrode strips, and the electrode strips converge at a minimum, of two ends of the sensing electrode.

2. The touch display device as claimed in claim 1, wherein the sum of the widths of the plurality of electrode strips of the sensing electrode is less than the width of the driving electrode.

3. The touch display device as claimed in claim 1, wherein the plurality of electrode strips further converge between two adjacent driving electrodes.

4. The touch display device as claimed in claim 1, further comprising a substrate,
wherein the plurality of driving electrodes and plurality of sensing electrodes are disposed on two opposite surfaces of the substrate, respectively.

5. The touch display device as claimed in claim 1, further comprising a substrate,
wherein the plurality of driving electrodes and plurality of sensing electrodes are disposed on the same surface of the substrate.

6. The touch display device as claimed in claim 5, wherein each of the driving electrodes is divided by the electrode strips into several areas, and the adjacent areas of the driving electrode are connected together by at least one bridge which strides across the electrode strip between the adjacent areas.

7. A touch panel, comprising:
a substrate;
a plurality of driving electrodes disposed in parallel in a first direction on a first surface of the substrate; and
a plurality of sensing electrodes disposed in parallel in a second direction on a second surface of the substrate,
wherein each of the sensing electrodes are split into a plurality of electrode strips, and the electrode strips converge at a minimum, of two ends of the sensing electrode.

8. The touch panel as claimed in claim 7, wherein the sum of the widths of the plurality of electrode strips of the sensing electrode is less than the width of the driving electrode.

9. The touch panel as claimed in claim 7, wherein the plurality of electrode strips further converge between two adjacent driving electrodes.

10. A touch panel, comprising:
a substrate;
a plurality of driving electrodes disposed in parallel in a first direction on a first surface of the substrate; and
a plurality of sensing electrodes disposed in parallel in a second direction on the first surface of the substrate,
wherein each of the sensing electrodes are split into a plurality of electrode strips, and the electrode strips converge at a minimum, of two ends of the sensing electrode.

11. The touch panel as claimed in claim 10, wherein the sum of the widths of the plurality of electrode strips of the sensing electrode is less than the width of the driving electrode.

12. The touch panel as claimed in claim 10, wherein the plurality of electrode strips further converge between two adjacent driving electrodes.

13. The touch panel as claimed in claim 10, wherein each of the driving electrodes is divided by the electrode strips into several areas, and the adjacent areas of the driving electrode are connected together by at least one bridge which strides across the electrode strip between the adjacent areas.
